(19) United States
(12) Patent Application Publication
(10) Pub. No.: US 2024/0206148 A1
(43) Pub. Date: Jun. 20, 2024

(54) MEMORY DEVICES AND METHODS FOR FORMING THE SAME

(71) Applicant: YANGTZE MEMORY TECHNOLOGIES CO., LTD., Wuhan (CN)

(72) Inventors: Kun Zhang, Wuhan (CN); Yuancheng Yang, Wuhan (CN); Dongxue Zhao, Wuhan (CN); Tao Yang, Wuhan (CN); Lei Liu, Wuhan (CN); Di Wang, Wuhan (CN); Wenxi Zhou, Wuhan (CN); Zhiliang Xia, Wuhan (CN); Zongliang Huo, Wuhan (CN)

(21) Appl. No.: 18/089,472

(22) Filed: Dec. 27, 2022

(30) Foreign Application Priority Data
Dec. 16, 2022 (CN) 202211622286.8

(51) Int. Cl. H10B 12/00; H01L 23/00; H01L 25/00; H01L 25/065; H01L 25/18

(52) U.S. Cl. CPC H01L 27/10802; H01L 24/08; H01L 24/80; H01L 25/0657; H01L 25/18; H01L 25/50; H01L 2224/08145; H01L 2224/80895; H01L 2224/80896; H01L 2924/1431; H01L 2924/1436

(57) ABSTRACT

A memory device includes a first semiconductor layer, a first memory array, a second memory array, and a first peripheral circuit. The first memory array is disposed on a first side of the first semiconductor layer. The first memory array includes first memory cells, and first split structures. The second memory array is disposed on a second side of the first semiconductor layer opposite to the first side. The second memory array includes second memory cells, and second split structures. The first peripheral circuit including a first peripheral device disposed on the first memory array.

### CROSS-REFERENCE TO RELATED APPLICATIONS

This application claims the benefit of priority to Chinese Application No. 202211622286.8, filed Dec. 16, 2022, which is incorporated herein by reference in its entirety.

### BACKGROUND

The present disclosure relates to memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a memory device is disclosed. The memory device includes a first semiconductor layer, a first memory array, a second memory array, and a first peripheral circuit. The first memory array is disposed on a first side of the first semiconductor layer. The first memory array includes first memory cells, and first split structures. The second memory array is disposed on a second side of the first semiconductor layer opposite to the first side. The second memory array includes second memory cells, and second split structures. The first peripheral circuit including a first peripheral device disposed on the first memory array.

In some implementations, each first memory cell includes a first semiconductor body extending in a first direction, a first end of the first semiconductor body is in contact with the first semiconductor layer; a first word line extending in a second direction perpendicular to the first direction; a first plate line extending in the second direction; and a first dielectric layer disposed between the first semiconductor body and the first word line and the first plate line.

In some implementations, the first plate line includes conductive lines extending in the second direction.

In some implementations, the first semiconductor body and the first semiconductor layer include a same semiconductor material.

In some implementations, the first peripheral circuit is disposed on a first side of a second semiconductor layer and a second side of the second semiconductor layer opposite to the first side is bonded to the first memory array.

In some implementations, the first peripheral circuit is disposed on a first side of a second semiconductor layer and a second side of the second semiconductor layer opposite to the first side is formed a pad-out structure.

In some implementations, each first split structure includes a split core, and a second dielectric layer surrounding the split core. The second dielectric layer is disposed between a first end of the split core and the first semiconductor layer.

In some implementations, each first split structure includes a split core, and a second dielectric layer surrounding the split core. A first end of the split core is in contact with the first semiconductor layer.

In some implementations, the memory device further includes a contact structure penetrating the first semiconductor layer, the first memory array, and the second memory array. The contact structure is in contact with the first peripheral circuit and the second peripheral circuit.

In a further aspect, a memory device is disclosed. The memory device includes a first semiconductor layer, a first memory array, a second memory array, and a first peripheral circuit. The first memory array includes first memory cells disposed on a first side of the first semiconductor layer. Each first memory cell includes a first semiconductor body extending in a first direction, a first end of the first semiconductor body is in contact with the first semiconductor layer; a first word line extending in a second direction perpendicular to the first direction; a first plate line extending in the second direction; and a first dielectric layer disposed between the first semiconductor body and the first word line and the first plate line. The second memory array includes second memory cells disposed on a second side of the first semiconductor layer opposite to the first side. Each second memory cell includes a second semiconductor body extending in the first direction, a first end of the second semiconductor body is in contact with the first semiconductor layer; a second word line extending in the second direction; a second plate line extending in the second direction; and a second dielectric layer disposed between the second semiconductor body and the second word line and the second plate line. The first peripheral circuit includes a first peripheral device disposed on the first memory array.

In some implementations, the first memory array further includes a plurality of first split structures. Each first split structure is disposed between two adjacent first memory cells.

In some implementations, each first split structure includes a split core, and a third dielectric layer surrounding the split core. The third dielectric layer is disposed between a first end of the split core and the first semiconductor layer.

In some implementations, each first split structure includes a split core, and a third dielectric layer surrounding the split core. A first end of the split core is in contact with the first semiconductor layer.

In still a further aspect, a method for forming a memory device is disclosed. A first memory array including first memory cells is formed on a first surface of a first semiconductor layer. The first memory array includes a first channel structure extending in a first direction, and a first word line and a first plate line extending in a second direction perpendicular to the first direction. A first peripheral circuit includes a first peripheral device on the first memory array. A second memory array including second memory cells is formed on a second surface of the first semiconductor layer opposite to the first surface. The second memory array includes a second channel structure extending in the first direction. A second word line and a second plate line extend in the second direction. A second peripheral circuit including a second peripheral device is formed on the second memory array.

In some implementations, a dielectric stack including interleaved first dielectric layers and second dielectric layers is formed on the first semiconductor layer. The first channel structure is formed in the dielectric stack extending in the first direction. The second dielectric layers are replaced with the first word line and the first plate line extending in the second direction. A bit line is formed in contact with the first channel structure.

In some implementations, a split structure is formed between two adjacent first memory cells.

In some implementations, a split opening penetrating the dielectric stack extending in the first direction is formed to expose the first semiconductor layer. A third dielectric layer is formed in sidewalls of the split opening. A split core is formed in the split opening.

In some implementations, a bottom surface of the split core is below a top surface of the first semiconductor layer.

In some implementations, a second semiconductor layer is formed on the first memory array. The first peripheral circuit including the first peripheral device is formed on the second semiconductor layer.

In some implementations, the first peripheral circuit including the first peripheral device is formed on a second semiconductor layer. The first peripheral circuit is bonded with the first memory array in a face-to-face manner.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIGS. 1A-1B illustrate schematic views of cross-sections of memory devices, according to some aspects of the present disclosure.

FIG. 2 illustrates a schematic view of a cross-section of a memory device, according to some aspects of the present disclosure.

FIG. 3 illustrates a schematic view of a cross-section of a memory cell, according to some aspects of the present disclosure.

FIG. 4 illustrates a side view of a cross-section of a memory device, according to some aspects of the present disclosure.

FIG. 5 illustrates a side view of a cross-section of a memory device, according to some aspects of the present disclosure.

FIG. 6 illustrates a side view of a cross-section of a memory device, according to some aspects of the present disclosure.

FIG. 7 illustrates a side view of a cross-section of a memory device, according to some aspects of the present disclosure.

FIGS. 8A-8B illustrate side views of cross-sections of split structures, according to some aspects of the present disclosure.

FIGS. 9A-9B illustrate plan views of memory devices, according to some aspects of the present disclosure.

FIGS. 10-15 illustrate a fabrication process for forming a memory device, according to some aspects of the present disclosure.

FIG. 16 illustrates a flowchart of a method for forming a memory device, according to some aspects of the present disclosure.

FIG. 17 illustrates a block diagram of an exemplary system having a memory device, according to some aspects of the present disclosure.

FIG. 18A illustrates a diagram of an exemplary memory card having a memory device, according to some aspects of the present disclosure.

FIG. 18B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

Transistors are used as the switch or selecting devices in the memory cells of some memory devices. However, the planar transistors commonly used in existing memory cells usually have a horizontal structure with buried word lines in the substrate and bit lines above the substrate. Since the source and drain of a planar transistor are disposed laterally at different locations, which increases the area occupied by the transistor. The design of planar transistors also complicates the arrangement of interconnected structures, such as word lines and bit lines, coupled to the memory cells, for example, limiting the pitches of the word lines and/or bit lines, thereby increasing the fabrication complexity and reducing the production yield. Moreover, because the bit lines and the storage units (e.g., capacitors) are arranged on the same side of the planar transistors (above the transistors and substrate), the bit line process margin is limited by the storage units, and the coupling capacitance between the bit lines and storage units, such as capacitors, are increased. Planar transistors may also suffer from a high leakage current as the saturated drain current keeps increasing, which is undesirable for the performance of memory devices.

On the other hand, as the number of memory cells keeps increasing, to maintain the same chip size, the dimensions of the components in the memory cell array, such as transistors, word lines, and/or bit lines, need to keep decreasing in order not to significantly reduce the memory cell array efficiency.

To address one or more of the aforementioned issues, the present disclosure introduces a memory device having a vertical arrangement of the source/drain terminals, and a word line gate and a plate line gate to select and store data in the memory device. Compared to the existing memory cells, the memory device in the present disclosure has vertically arranged transistors (i.e., the drain and source are overlapped in the plan view) that can reduce the area of the transistor as well as simplify the layout of the interconnect structures, e.g., metal wiring the word lines and bit lines, which can reduce the fabrication complexity and improve the yield. In addition, the memory device in the present disclosure does not need a capacitor storage device to store data in the memory device.

Furthermore, consistent with the scope of the present disclosure, according to some aspects of the present disclosure, the memory cell array having vertical transistors and the peripheral circuits of the memory cell array can be formed on the same wafer in a side-by-side manner, i.e., next to one another. The number of wafers needed to fabricate the same number of memory devices and the complexity involved in the bonding process can be reduced compared with the face-to-face bonding scheme.

In some implementations, the vertical transistors disclosed herein may include dynamic flash memories (DFM), which is a capacitor-less type of random access memory (RAM). The DFM uses a dual gate surrounding gate transistor (SGT) to eliminate capacitors and increase the bit density of the memory.

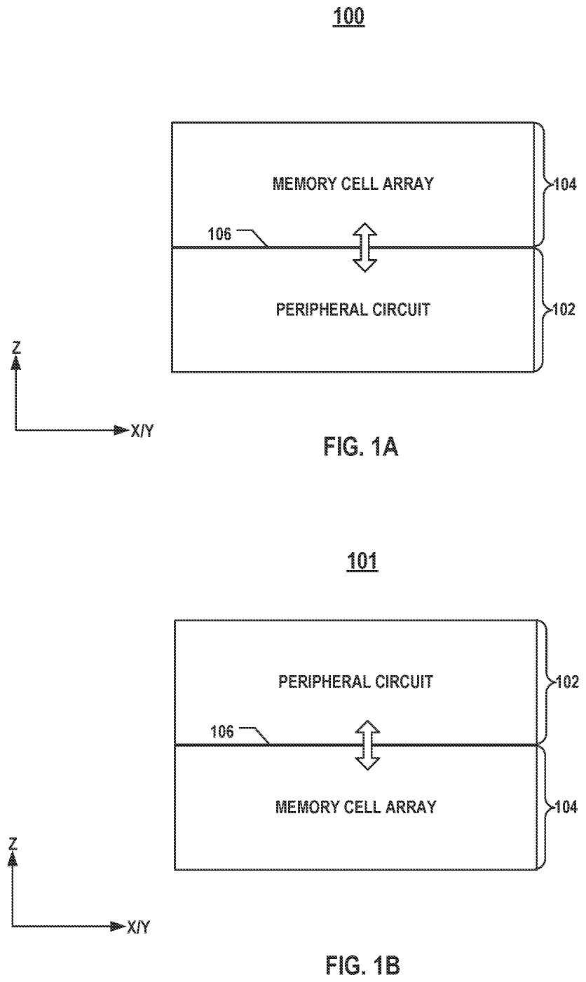

FIG. 1A illustrates a schematic view of a cross-section of a 3D memory device 100, according to some aspects of the present disclosure. 3D memory device 100 represents an example of a bonded chip. The components of 3D memory device 100 (e.g., memory cell array and peripheral circuits) can be formed separately on different substrates and then jointed to form a bonded chip. 3D memory device 100 can include a first semiconductor structure 102 including the peripheral circuits of a memory cell array. 3D memory device 100 can also include a second semiconductor structure 104 including the memory cell array. The peripheral circuits (a.k.a. control and sensing circuits) can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in first semiconductor structure 102 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

As shown in FIG. 1A, 3D memory device 100 can also include first semiconductor structure 104 including an array of memory cells (memory cell array) that can use transistors as the switch and selecting devices. For ease of description, a DFM cell array may be used as an example for describing the memory cell array in the present disclosure. But it is understood that the memory cell array is not limited to the DFM cell array and may include any other suitable types of memory cell arrays that can use transistors as selecting devices and storage units.

As shown in FIG. 1A, 3D memory device 100 further includes a bonding interface 106 vertically between (in the vertical direction, e.g., the z-direction in FIG. 1A) first semiconductor structure 102 and second semiconductor structure 104. As described below in detail, first and second semiconductor structures 102 and 104 can be fabricated separately (and in parallel in some implementations) such that the thermal budget of fabricating one of first and second semiconductor structures 102 and 104 does not limit the processes of fabricating another one of first and second semiconductor structures 102 and 104. Moreover, a large number of interconnects (e.g., bonding contacts) can be formed through bonding interface 106 to make direct, short-distance (e.g., micron-level) electrical connections between first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory cell array in second semiconductor structure 104 and the peripheral circuits in first semiconductor structure 102 can be performed through the interconnects (e.g., bonding contacts) across bonding interface 106. By vertically integrating first and second semiconductor structures 102 and 104, the chip size can be reduced, and the memory cell density can be increased.

It is understood that the relative positions of stacked first and second semiconductor structures 102 and 104 are not limited. FIG. 1B illustrates a schematic view of a cross-section of another exemplary 3D memory device 101, according to some implementations. Different from 3D memory device 100 in FIG. 1A in which second semiconductor structure 104 including the memory cell array is above first semiconductor structure 102 including the peripheral circuits, in 3D memory device 101 in FIG. 1B, first semiconductor structure 102 including the peripheral circuit is above second semiconductor structure 104 including the memory cell array. Nevertheless, bonding interface 106 is formed vertically between first and second semiconductor structures 102 and 104 in 3D memory device 101, and first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between the memory cell array in second semiconductor structure 104 and the peripheral circuits in first semiconductor structure 102 can be performed through the interconnects (e.g., bonding contacts) across bonding interface 106.

It is noted that x, y, and z axes are included in FIGS. 1A and 1B to further illustrate the spatial relationship of the components in 3D memory devices 100 and 101. The substrate of the 3D memory device includes two lateral surfaces extending laterally in the x-y plane: a top surface on the front side of the wafer on which the semiconductor devices can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the 3D memory device is determined relative to the substrate of the 3D memory device in the z-direction (the vertical direction perpendicular to the x-y plane, e.g., the thickness direction of the substrate) when the substrate is positioned in the lowest plane of the 3D memory device in the z-direction. The same notion for describing the spatial relationships is applied throughout the present disclosure.

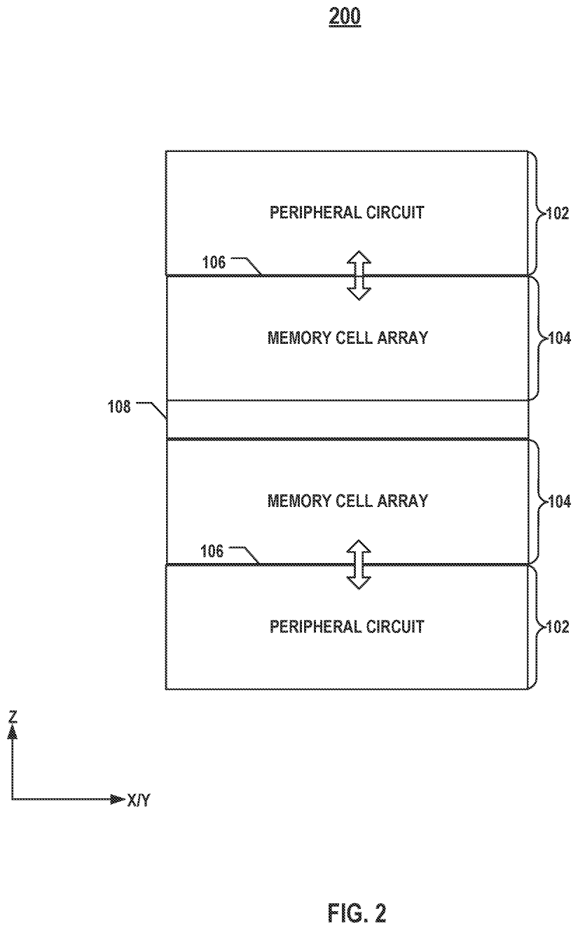

FIG. 2 illustrates a schematic view of a cross-section of a memory device 200, according to some aspects of the present disclosure. As shown in FIG. 2, two second semiconductor structures 104 may be formed on a same substrate 108. Specifically, two second semiconductor structures 104 may be formed on two opposite surfaces of substrate 108. In some implementations, one second semiconductor structure 104 may be formed on one surface of substrate 108 first, and then substrate 108 may be flipped over and another second semiconductor structure 104 may be formed on the other surface of substrate 108.

As shown in FIG. 2, each of two second semiconductor structures may separately have first semiconductor structures 102 formed thereon. Bonding interface 106 may be vertically between first semiconductor structure 102 and second semiconductor structure 104. The detailed structure and fabrication process of two second semiconductor structures 104 formed on two different surfaces of substrate 108 will be discussed later.

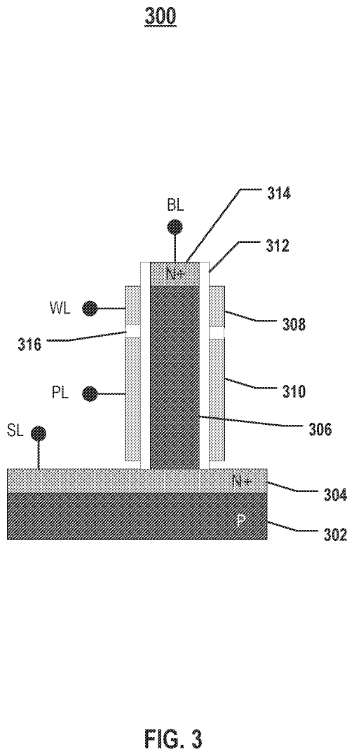

FIG. 3 illustrates a schematic view of a cross-section of a memory cell 300, according to some aspects of the present disclosure. In some implementations, the memory cell array includes an array of memory cells 300. For ease of description, a DFM cell array may be used as an example for describing the memory cell array in the present disclosure. But it is understood that the memory cell array is not limited to DFM cell array and may include any other suitable types of memory cell arrays that can use transistors as selecting device and storage unit.

Memory cell 300 includes a semiconductor body 306 formed on a semiconductor layer 302, e.g., a semiconductor substrate. In some implementations, semiconductor body 306 may include P-type or intrinsic conductivity-type silicon. In some implementations, semiconductor layer 302 may include a silicon substrate. A first end 304 and a second end 314 of semiconductor body 306 may include N+ layers. As used herein, the N+ layers are semiconductor regions that contain a donor impurity in high concentration. In some implementations, first end 304 and second end 314 function as the source and the drain of the transistor, e.g., the memory cell. Portions of semiconductor body 306 between first end 304 and second end 314 may function as the channel region of the transistor. Around semiconductor body 306, a dielectric layer 312 may be formed as a gate insulating layer of the transistor. A word line gate 308 and a plate line gate 310 may be formed around dielectric layer 312 and may function as gate conductor layers. In some implementations, word line gate 308 and plate line gate 310 may be further isolated from each other by a dielectric layer 316.

The channel region, which is a portion of semiconductor body 306 between first end 304 and second end 314, may be constituted by a first channel layer surrounded by plate line gate 310 and a second channel layer surrounded by word line gate 308. Accordingly, first end 304 and second end 314 that function as the source and the drain, the channel region, dielectric layer 312, word line gate 308, and plate line gate 310 constitute memory cell 300. First end 304 that functions as the source is connected to a source line SL, second end 314 that functions as the drain is connected to a bit line BL, plate line gate 310 is connected to a plate line PL, and word line gate 308 is connected to a word line WL. In some implementations, the structure is such that the gate capacitance of plate line gate 310 to which the plate line PL is connected is larger than the gate capacitance of word line gate 308 to which the word line WL is connected.

In some implementations, to make the gate capacitance of plate line gate 310 to which the plate line PL is connected larger than the gate capacitance of word line gate 308 to which the word line WL is connected, the gate length of plate line gate 310 may be made longer than the gate length of word line gate 308. Alternatively, instead of making the gate length of plate line gate 310 longer than the gate length of word line gate 308, plate line gate 310 may be formed by a plurality of gates. The channel region between first end 304 and second end 314 is electrically isolated from semiconductor layer 302 and functions as a floating body.

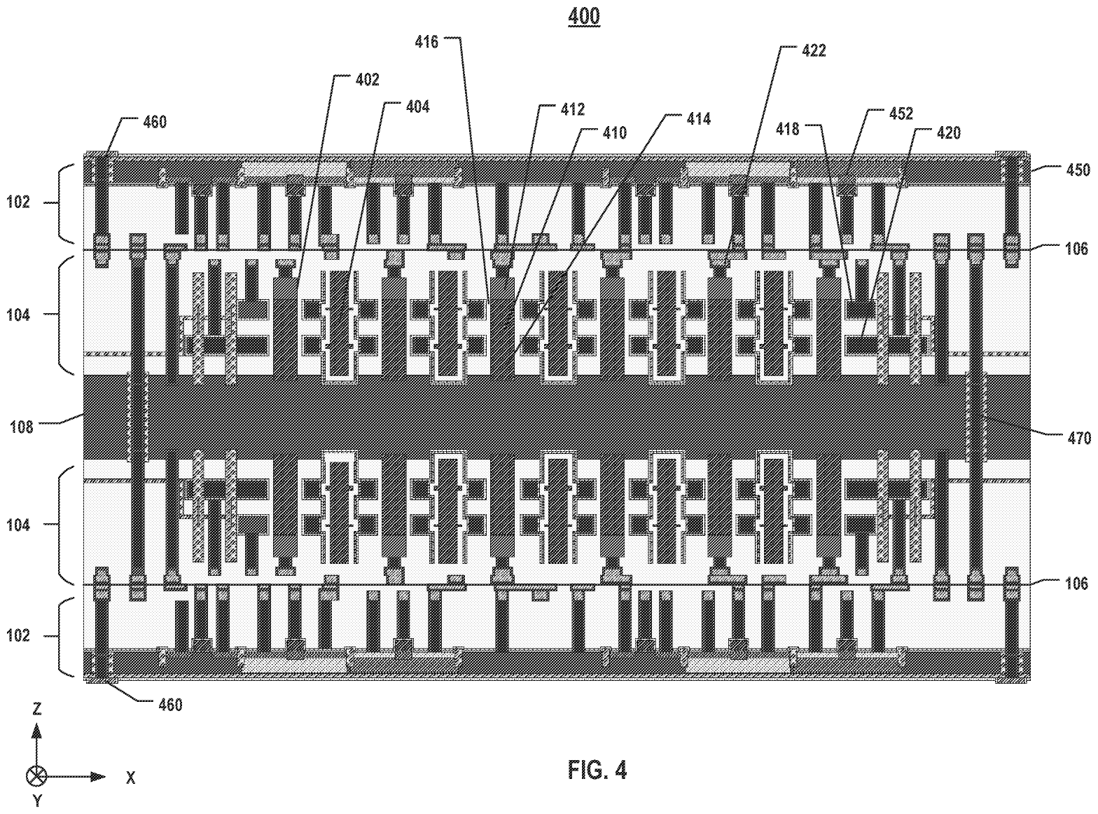

FIG. 4 illustrates a side view of a cross-section of a memory device 400, according to some aspects of the present disclosure. Memory device 400 may be one example of memory device 200 that includes two second semiconductor structures 104 formed on two opposite surfaces of substrate 108, and two first semiconductor structures 102 separately formed on two second semiconductor structure 104. First and second semiconductor structures 102 and 104 are jointed at bonding interface 106 therebetween, according to some implementations. It is understood that FIG. 4 is for illustrative purposes only and may not necessarily reflect the actual device structure (e.g., interconnections) in practice.

In some implementations, second semiconductor structures 104 may be formed on two opposite surfaces of substrate 108 and substrate 108 may be a semiconductor layer, e.g., part of a carrier wafer, which can include silicon (e.g., single crystalline silicon, c-Si), silicon germanium (SiGe), gallium arsenide (GaAs), germanium (Ge), silicon-on-insulator (SOI), or any other suitable materials. Second semiconductor structures 104 may be the memory array including a plurality of memory cells 402 formed on substrate 108. A plurality of split structures 404 may be disposed between two memory cells 402. It is understood that the number of split structures 404 and memory cells 402 shown in FIG. 4 is for illustrative purposes only and may have a different design as required. For example, two or more split structures 404 may be disposed between two memory cells 402. For another example, two or more memory cells 402 may be disposed between two split structures 404.

Each memory cell 402 includes a semiconductor body 410. A first end 412 and a second end 414 are formed at two sides of semiconductor body 410. In some implementations, semiconductor body 410 may include semiconductor materials, such as single crystalline silicon, polysilicon, amorphous silicon, Ge, any other semiconductor materials, or any combinations thereof. In one example, semiconductor body 410 may include single crystalline silicon.

First end 412 and second end 414 function as the source and the drain of memory cell 402. Portions of semiconductor body 410 between first end 412 and second end 414 may function as the channel region of memory cell 402. In some implementations, first end 412 and second end 414 may be doped with N-type dopants (e.g., P or As) or P-type dopants (e.g., B or Ga) at a desired doping level. In some implementations, a silicide layer, such as a metal silicide layer, may be formed between first end 412 and second end 414 (source and drain) and the bit line BL or source line SL contacts to reduce the contact resistance.

Around semiconductor body 410, a dielectric layer 416 may be formed as a gate insulating layer of memory cell 402. In some implementations, dielectric layer 416 (gate dielectric or gate insulating layer) may include dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof.

A word line 418 and a plate line 420 may be formed around dielectric layer 416 and may function as gate conductor layers. In some implementations, word line 418 and plate line 420 may be isolated from each other. It is understood that the word line gate electrodes (e.g., word line gate 308 in FIG. 3) may be part of word line 418 or extend in the word line direction (e.g., the x-direction) as word line 418, and the plate line gate electrodes (e.g., plate line gate 310 in FIG. 3) may be part of plate line 420 or extend in the plate line direction (e.g., the x-direction) as plate line 420.

In some implementations, word line 418 and plate line 420 (including the word line gate electrode and the plate line gate electrode) may include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, word line 418 and plate line 420 may include doped polysilicon, i.e., a gate poly. In some implementations, word line 418 and plate line 420 may include multiple conductive layers, such as a W layer over a TiN layer. In one example, the word line gate electrode and the plate line gate electrode may be a “gate oxide/gate poly” gate in which the gate dielectric includes silicon oxide, and the gate electrode includes doped polysilicon. In another example, the word line gate electrode and the plate line gate electrode may be a high-k metal gate (HKMG) in which the gate dielectric includes a high-k dielectric, and the gate electrode includes a metal.

As shown in FIG. 4, semiconductor body 410 extends along the z-direction, and first end 412 and second end 414, which function as the source/drain, are formed at the top and the bottom of semiconductor body 410. Word line 418 and plate line 420 may parallel to each other and extend along the x-direction perpendicular to the z-direction. A contact is formed above semiconductor body 410 in contact with first end 412, and a bit line 422 is formed above the contact. In some implementations, bit line 422 extends along the y-direction perpendicular to the x-direction and the z-direction. In some implementations, semiconductor body 410 may be formed from substrate 108 (e.g., by etching or epitaxy) and thus, may have the same semiconductor material (e.g., single crystalline silicon) as substrate 108.

In some implementations, first semiconductor structure 102 may include a substrate 450, and substrate 450 may be a semiconductor layer, e.g., part of a carrier wafer, which can include silicon (e.g., single crystalline silicon, c-Si), SiGe, GaAs, Ge, SOI, or any other suitable materials. One or more peripheral circuits including one or more peripheral devices 452 are formed on substrate 450. In some implementations, the peripheral circuits may include any suitable digital, analog, and/or mixed-signal circuits used for facilitating the operations of the memory cell array.

As shown in FIG. 4, first semiconductor structure 102 can further include pad-out structures 460 above and beneath first semiconductor structure 102. In some implementations, pad-out structures 460 may include interconnects, e.g., contact pads, in one or more interlayer dielectric (ILD) layers. In some implementations, the interconnects in pad-out structures 460 may transfer electrical signals between memory device 400 and outside circuits, e.g., for pad-out purposes.

In some implementations, memory device 400 may further include one or more contact structures 470 extending through substrate 108 to couple two second semiconductor structures 104. Pad-out structures 460 and contact structures 470 can include conductive materials including, but not limited to, W, Co, Cu, Al, silicides, or any combination thereof. In some implementations, contact structures 470 includes a via surrounded by a dielectric spacer (e.g., having silicon oxide) to electrically separate the via from substrate 108. Depending on the thickness of substrate 108, contact structure 470 may be an interlayer via (ILV) having a depth in the submicron-level (e.g., between 10 nm and 1 μm), or a through substrate via (TSV) having a depth in the micron- or tens micron-level (e.g., between 1 μm and 100 μm).

In some implementations, first semiconductor structure 102 may be bonded on top or bottom of second semiconductor structure 104 in a face-to-face manner at bonding interface 106, as shown in FIG. 4. In some implementations, bonding interface 106 is an implementation of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 106 is the place at which the bonding layers are met and bonded. In practice, bonding interface 106 can be a layer with a certain thickness that includes the bonding layers of first semiconductor structure 102 and second semiconductor structure 104.

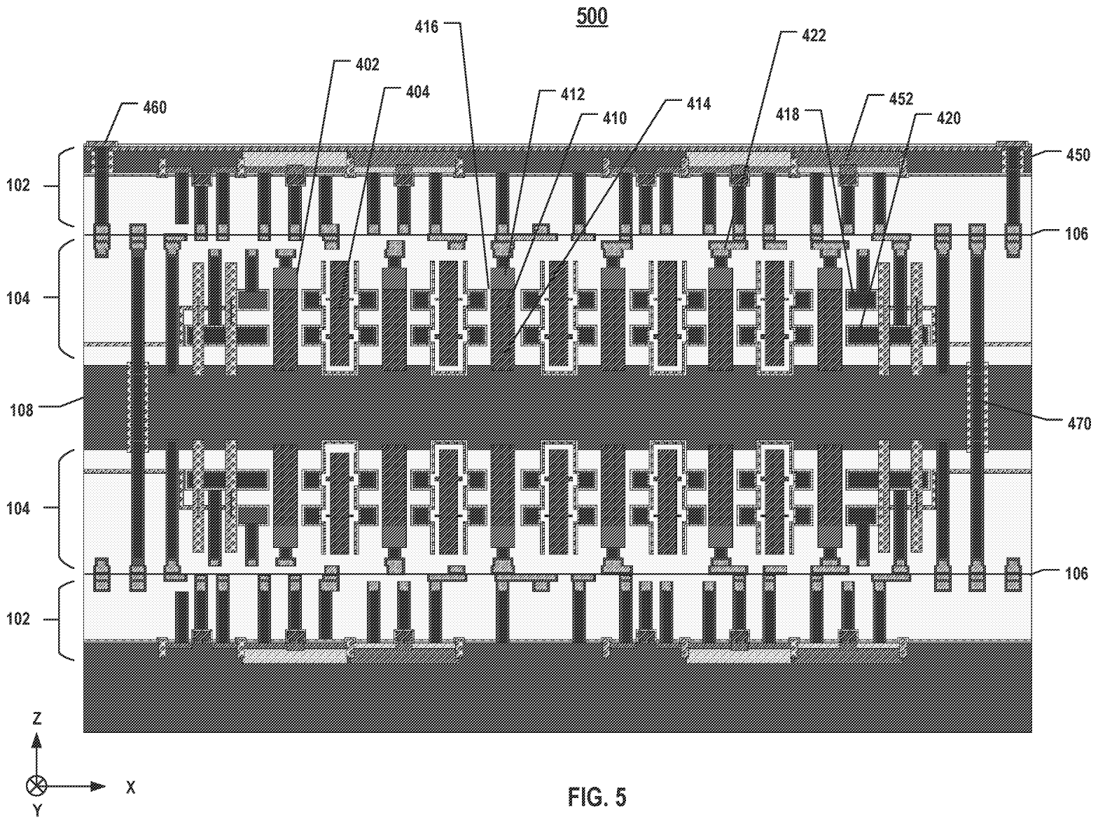

FIG. 5 illustrates a side view of a cross-section of a memory device 500, according to some aspects of the present disclosure. Memory device 500 may be another example of memory device 200 that includes two second semiconductor structures 104 formed on two opposite surfaces of substrate 108, and two first semiconductor structures 102 separately formed on two second semiconductor structure 104. First and second semiconductor structures 102 and 104 are jointed at bonding interface 106 therebetween, according to some implementations. It is understood that FIG. 5 is for illustrative purposes only and may not necessarily reflect the actual device structure (e.g., interconnections) in practice.

The devices and materials forming first and second semiconductor structures 102 and 104 of memory device 500 may be similar to first and second semiconductor structures 102 and 104 of memory device 400. However, as shown in FIG. 5, pad-out structures 460 may be formed on only one side of memory device 500. In other words, the interconnects in pad-out structures 460 may transfer electrical signals between memory device 500 and outside circuits via one side of memory device 500.

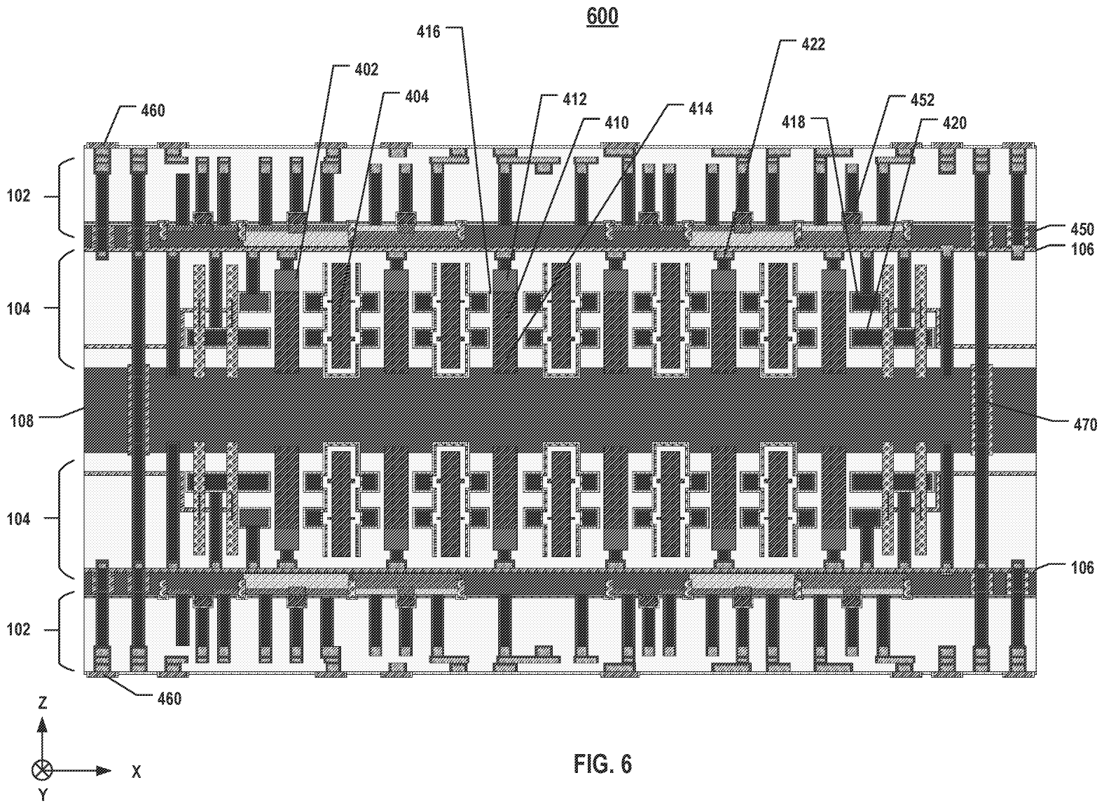

FIG. 6 illustrates a side view of a cross-section of a memory device 600, according to some aspects of the present disclosure. Memory device 600 may still be another example of memory device 200 that includes two second semiconductor structures 104 formed on two opposite surfaces of substrate 108, and two first semiconductor structures 102 separately formed on two second semiconductor structure 104. First and second semiconductor structures 102 and 104 are jointed at bonding interface 106 therebetween, according to some implementations. It is understood that FIG. 6 is for illustrative purposes only and may not necessarily reflect the actual device structure (e.g., interconnections) in practice.

As shown in FIG. 6, second semiconductor structures 104 may be formed on two opposite surfaces of substrate 108, and the structures and materials of second semiconductor structures 104 in memory device 600 may be similar to the structures and materials of second semiconductor structures 104 in memory devices 400 and 500.

In some implementations, first semiconductor structures 102 in memory device 600 may include substrate 450, and substrate 450 may be a semiconductor layer bonded to second semiconductor structures 104 or formed on second semiconductor structures 104, as shown in FIG. 6. In some implementations, substrate 450 may include silicon (e.g., single crystalline silicon, c-Si), SiGe, GaAs, Ge, SOI, or any other suitable materials. One or more than one peripheral circuit including one or more than one peripheral device 452 is formed on substrate 450. In some implementations, the peripheral circuits may include any suitable digital, analog, and/or mixed-signal circuits used for facilitating the operations of the memory cell array.

As shown in FIG. 6, substrate 450 is in contact with second semiconductor structures 104. In some implementations, after forming second semiconductor structures 104 on one side of substrate 108, substrate 450 may be directly formed on second semiconductor structures 104, and then first semiconductor structure 102 is formed on substrate 450. Then, substrate 108 may be flipped over to form another second semiconductor structure 104 on the other side of substrate 108, and substrate 450 and first semiconductor structure 102 are formed sequentially.

In some implementations, first semiconductor structure 102 may further include pad-out structures 460 above and beneath first semiconductor structure 102. In some implementations, pad-out structures 460 may include interconnects, e.g., contact pads, in one or more ILD layers. In some implementations, the interconnects in pad-out structures 460 may transfer electrical signals between memory device 600 and outside circuits, e.g., for pad-out purposes.

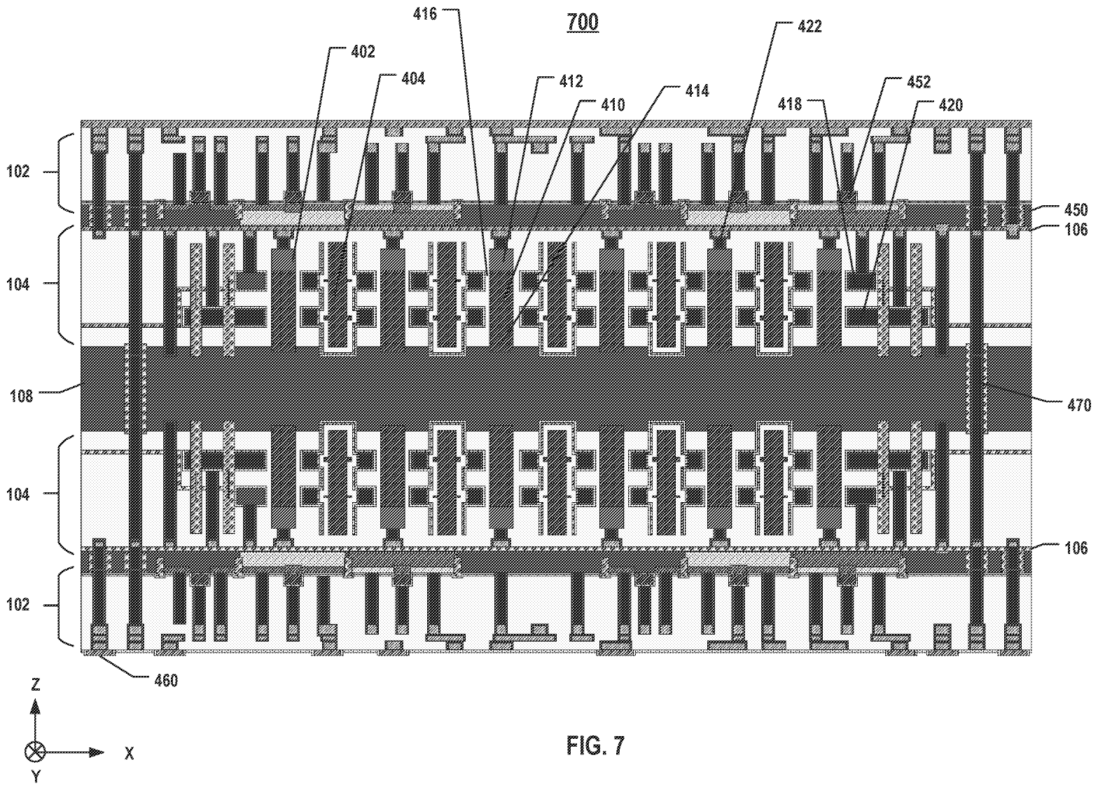

FIG. 7 illustrates a side view of a cross-section of a memory device 700, according to some aspects of the present disclosure. Memory device 700 may still be another example of memory device 200 that includes two second semiconductor structures 104 formed on two opposite surfaces of substrate 108, and two first semiconductor structures 102 separately formed on two second semiconductor structures 104. First and second semiconductor structures 102 and 104 are jointed at bonding interface 106 therebetween, according to some implementations. It is understood that FIG. 7 is for illustrative purposes only and may not necessarily reflect the actual device structure (e.g., interconnections) in practice.

The devices and materials forming first and second semiconductor structures 102 and 104 of memory device 700 may be similar to first and second semiconductor structures 102 and 104 of memory device 600. However, as shown in FIG. 7, pad-out structures 460 may be formed on only one side of memory device 700. In other words, the interconnects in pad-out structures 460 may transfer electrical signals between memory device 700 and outside circuits via one side of memory device 700.

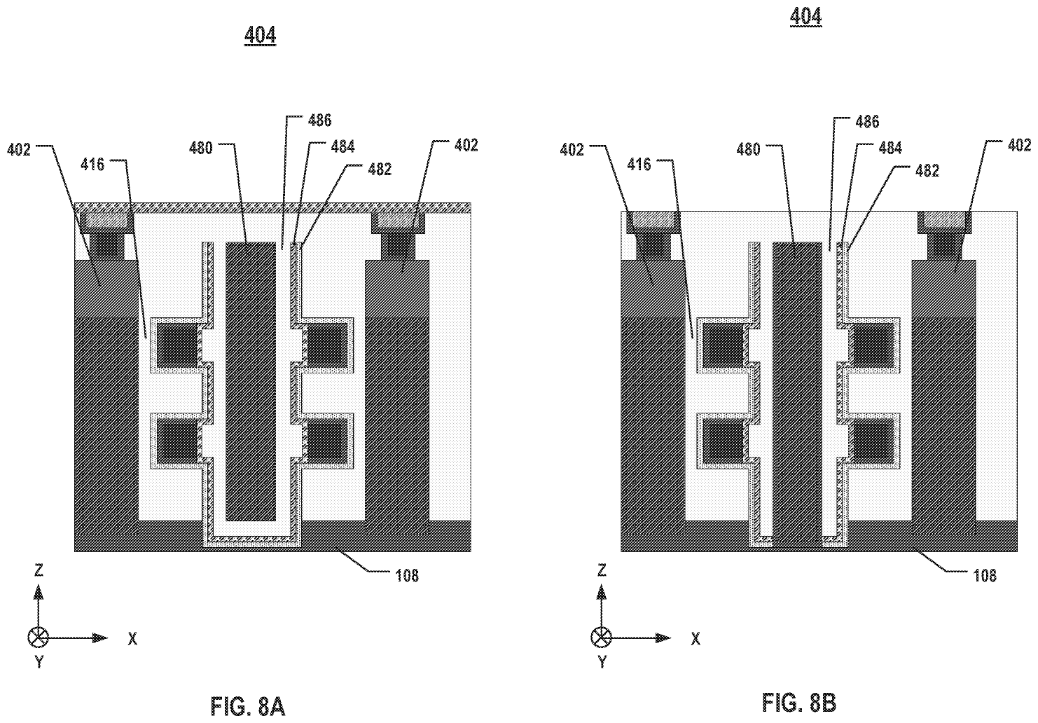

FIG. 8A illustrates a side view of a cross-section of split structure 404, according to some aspects of the present disclosure. As shown in FIG. 8A, split structure 404 may be disposed between two memory cells 402 and extend in the z-direction. In some implementations, split structure 404 may extend in the z-direction and the y-direction. In some implementations, split structure 404 may be formed by a dielectric material or a conductive material surrounded by dielectric spacers. In some implementations, split structure 404 may separate memory cells 402 into multiple memory blocks and/or memory fingers.

As shown in FIG. 8A, split structure 404 may include a split core 480 formed by filling the split opening with conductive materials including, but not limited to, W, Co, Cu, Al, polysilicon, silicides, or any combination thereof. Split structure 404 may further include a dielectric spacer surrounding split core 480. In some implementations, the dielectric spacer may include a first dielectric layer 482, a barrier layer 484, and a second dielectric layer 486. In some implementations, first dielectric layer 482 may be formed by materials including, but not limited to, silicon nitride, high-k dielectrics, such as aluminum oxide (Al₂O₃), hafnium oxide (HfO₂) or tantalum oxide (Ta₂O₅), or any combination thereof. Barrier layer 484 may prevent the fluorine atoms and/or ions, left during the gate formation operation, from further corroding second dielectric layer 486. In some implementations, barrier layer 484 may be formed by high-k dielectric materials including, but not limited to, silicon nitride, aluminum oxide (Al₂O₃), hafnium oxide (HfO₂) tantalum oxide (Ta₂O₅), zirconium oxide (ZrO₂), titanium oxide (TiO₂), or any combination thereof. In some implementations, second dielectric layer 486 may include silicon oxide.

As shown in FIG. 8A, first dielectric layer 482, barrier layer 484, and second dielectric layer 486 may surround the side and the bottom of split core 480. FIG. 8B illustrates a side view of a cross-section of another split structure 404, according to some aspects of the present disclosure. As shown in FIG. 8B, barrier layer 484, and second dielectric layer 486 may surround only the side of split core 480, and the bottom of split core 480 may be in contact with substrate 108. A bottom surface of split core 480 in FIG. 8B is below the top surface of substrate 108.

By utilizing the above structures, memory devices 400, 500, 600, and/or 700 may have a vertical arrangement of the source/drain terminals, which can reduce the area of the transistor as well as simplify the layout of the interconnect structures and reduce the fabrication complexity. In addition, memory devices 400, 500, 600, and/or 700 do not need a capacitor storage device to store data, and memory cells 402 on the same surface of substrate 108 may form a common source architecture to increase the cell density. Furthermore, memory cells 402 may be formed on two opposite surfaces of substrate 108 to further increase the density of memory devices 400, 500, 600, and/or 700.

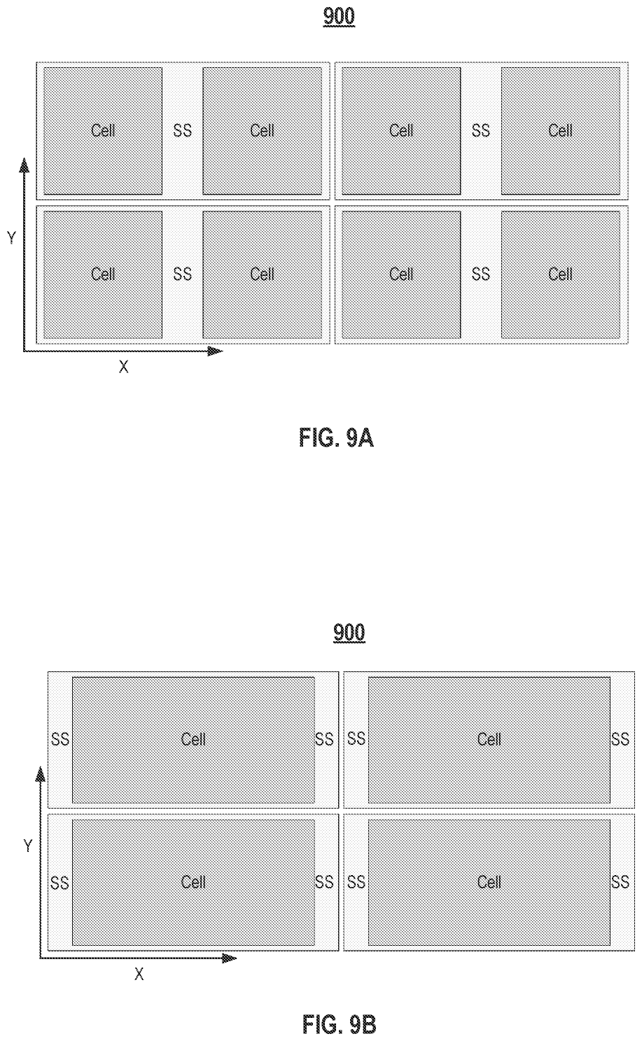

FIGS. 9A-9B illustrate plan views of memory devices 900, according to some aspects of the present disclosure. As shown in FIG. 9A, the staircase region SS may be disposed between two cell regions. As shown in FIG. 9B, the staircase region SS may be disposed at two sides of the cell regions in a plan view of memory devices 900.

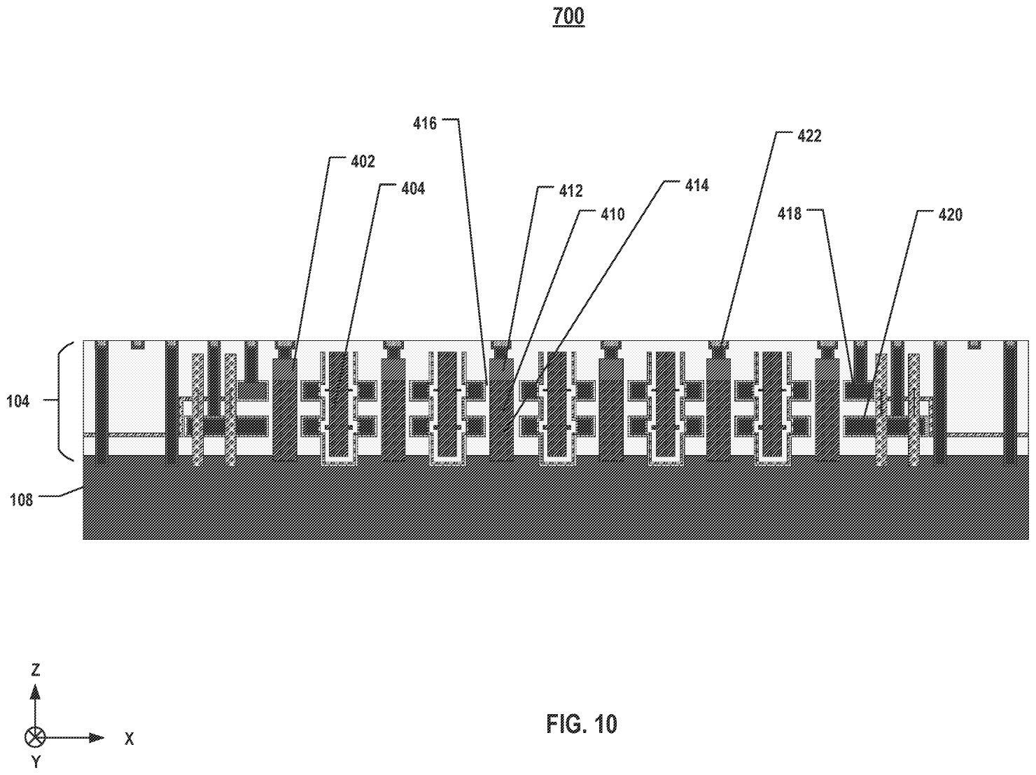

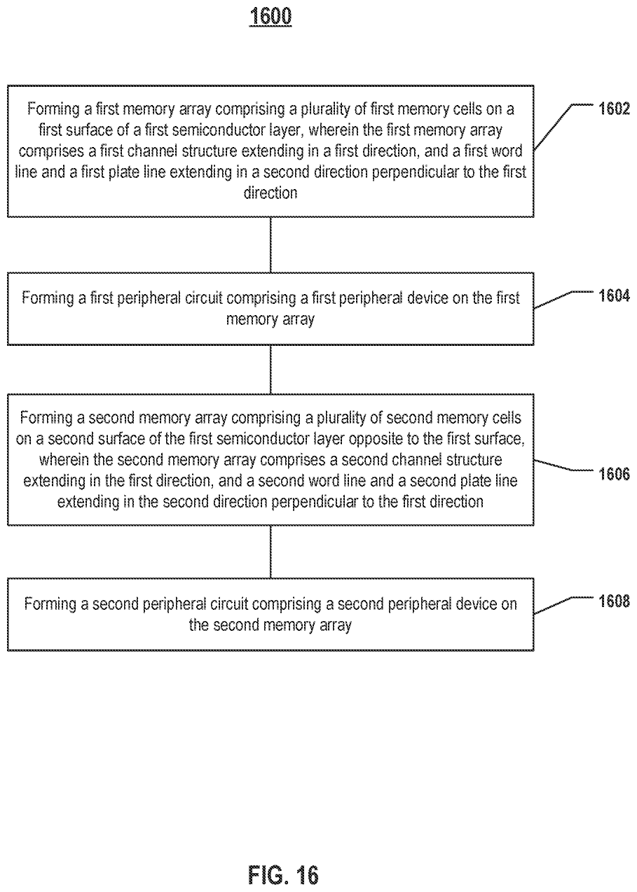

FIGS. 10-15 illustrate a fabrication process for forming memory device 700, according to some aspects of the present disclosure. FIG. 16 illustrates a flowchart of a method 1600 for forming memory device 700, according to some aspects of the present disclosure. For the purpose of better describing the present disclosure, the memory device 700 in FIGS. 10-15 and method 1600 in FIG. 16 will be discussed together. It is understood that the operations shown in method 1600 are not exhaustive and that other operations may be performed as well before, after, or between any of the illustrated operations. Further, some of the operations may be performed simultaneously, or in a different order than shown in FIGS. 10-15 and FIG. 16. It is also understood that FIGS. 10-15 illustrate memory device 700 as an example, and other implementations, including, but not limited to, memory devices 200, 400, 500, and 600, may also be suitable for the fabrication process.

As shown in FIG. 10 and operation 1602 in FIG. 16, a first memory array, e.g., second semiconductor structure 104, including a plurality of first memory cells 402 is formed on a first surface of a first semiconductor layer, e.g., substrate 108. The first memory array includes a first channel structure, e.g., semiconductor body 410, extending in the z-direction, and a first word line, e.g., word line 418, and a first plate line, e.g., plate line 420, extending in the x-direction.

In some implementations, a dielectric stack including interleaved first dielectric layers and second dielectric layers is formed on substrate 108. In some implementations, the first dielectric layers may include silicon oxide, and the second dielectric layers may include silicon nitride. In some implementations, the first dielectric layers and the second dielectric layers may be formed by one or more thin film deposition processes including, but not limited to, chemical vapor deposition (CVD), physical vapor deposition (PVD), atomic layer deposition (ALD), electroplating, electroless plating, or any combination thereof. In some implementations, a staircase structure may be formed at an edge of the dielectric stack.

Then, a channel structure is formed in the dielectric stack extending in the z-direction. In some implementations, a channel hole penetrating the dielectric stack is formed to expose substrate 108. In some implementations, the channel hole may be formed by a plurality of processes including, but not limited to, photolithography, dry/wet etch, and any other suitable processes. Then, dielectric layer 416 is formed on sidewalls of the channel hole, and semiconductor body 410 is formed in the channel hole.

The second dielectric layers are replaced with word line 418 and plate line 420 extending in the x-direction perpendicular to the z-direction. In some implementations, the second dielectric layers are removed by dry/wet etch and any other suitable processes to form a plurality of cavities. Then, word line 418 and plate line 420 are formed in the plurality of cavities. In some implementations, word line 418 and plate line 420 may be formed by thin film deposition, thermal growth, and any other suitable processes. In some implementations, word line 418 and plate line 420 may include any suitable conductive materials, such as polysilicon, metals (e.g., W, Cu, Al, etc.), metal compounds (e.g., TiN, TaN, etc.), or silicides. For example, word line 418 and plate line 420 may include doped polysilicon, i.e., a gate poly. In some implementations, word line 418 and plate line 420 may include multiple conductive layers, such as a W layer over a TiN layer.

A plurality of contacts may be formed above semiconductor body 410 in contact with first end 412, and bit line 422 is formed above the contact extending along the y-direction perpendicular to the x-direction and the z-direction.

In some implementations, operation 1602 may further include forming split structure 404 between two adjacent memory cells 402. In some implementations, a split hole may be formed extending in the z-direction between two adjacent memory cells 402. First dielectric layer 482, barrier layer 484, and second dielectric layer 486 may be sequentially formed in the split hole. Then, split core 480 is formed to fill in the split hole. In some implementations, split core 480 may be formed by conductive materials including, but not limited to, W, Co, Cu, Al, polysilicon, silicides, or any combination thereof. In some implementations, first dielectric layer 482 may be formed by materials including, but not limited to, silicon nitride, high-k dielectrics, such as aluminum oxide (Al₂O₃), hafnium oxide (HfO₂) or tantalum oxide (Ta₂O₅), or any combination thereof. In some implementations, barrier layer 484 may be formed by high-k dielectric materials including, but not limited to, silicon nitride, aluminum oxide (Al₂O₃), hafnium oxide (HfO₂) tantalum oxide (Ta₂O₅), zirconium oxide (ZrO₂), titanium oxide (TiO₂), or any combination thereof. In some implementations, second dielectric layer 486 may include silicon oxide.

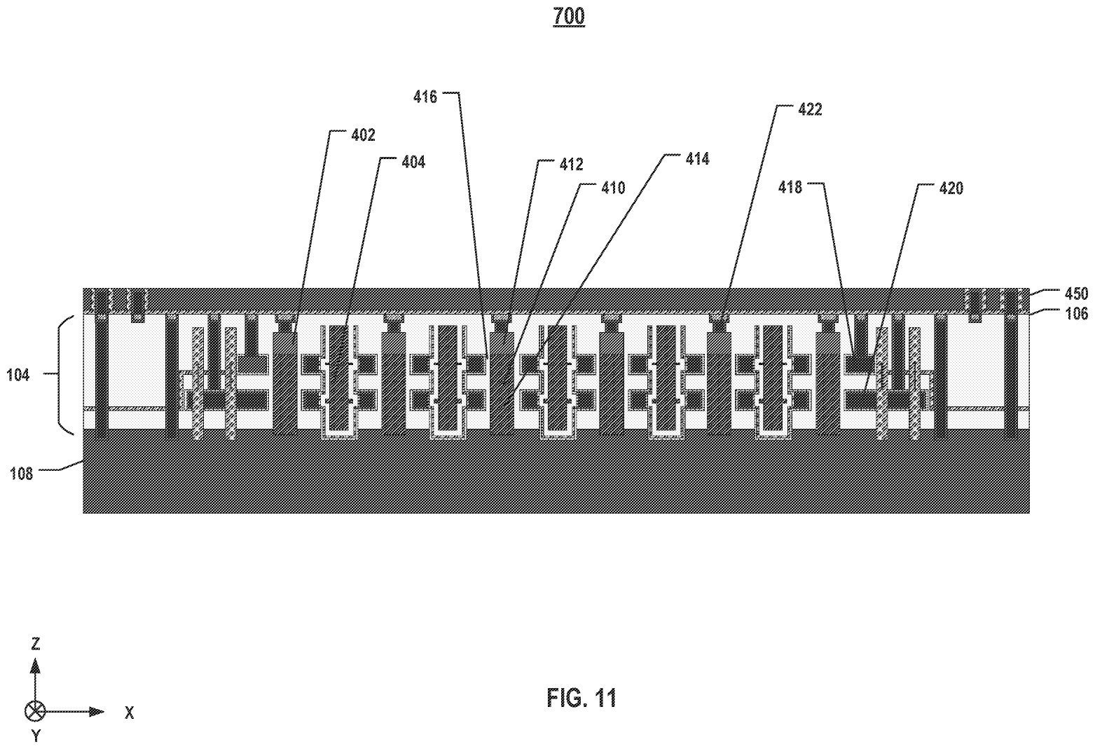

As shown in FIG. 11, a second semiconductor layer, e.g., substrate 450, is formed on second semiconductor structure 104. In some implementations, substrate 450 may be formed by one or more thin film deposition processes including, but not limited to, CVD, PVD, ALD, electroplating, electroless plating, or any combination thereof. In some implementations, substrate 450 may be a semiconductor layer, e.g., part of a carrier wafer, which can include silicon (e.g., single crystalline silicon, c-Si), SiGe, GaAs, Ge, SOI, or any other suitable materials.

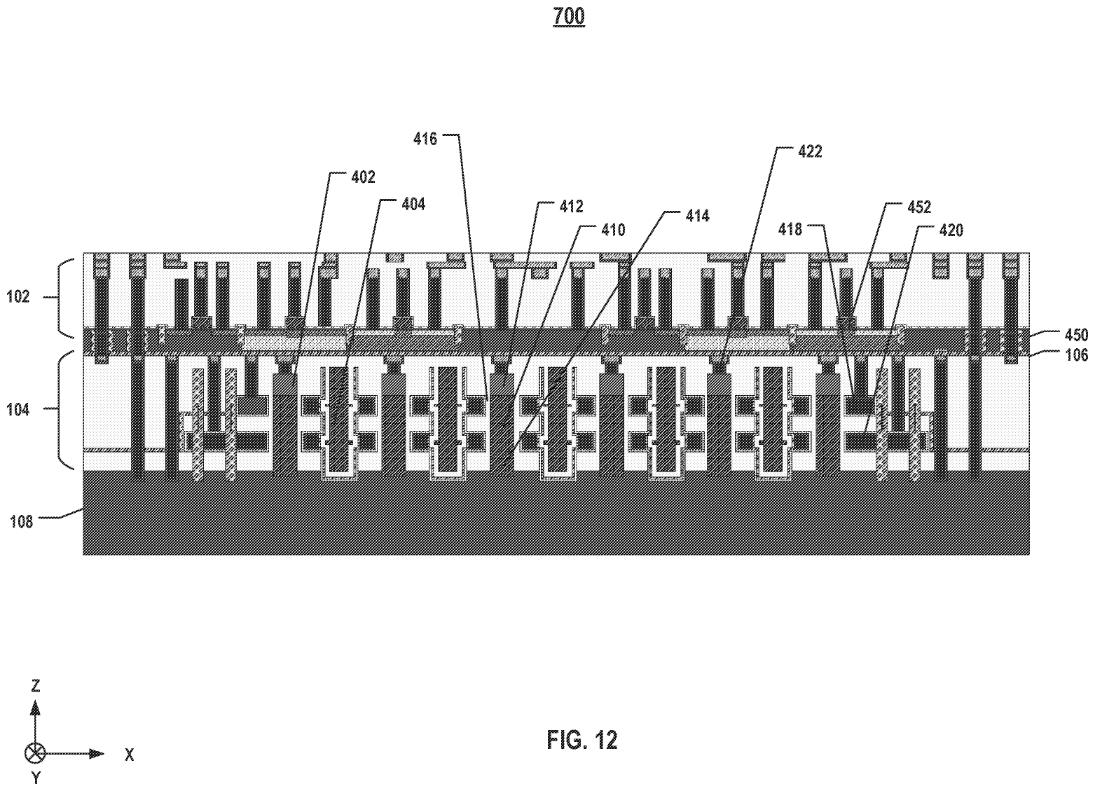

As shown in FIG. 12 and operation 1604 in FIG. 16, a first peripheral circuit, e.g., first semiconductor structure 102, including a first peripheral device, e.g., peripheral device 452, is formed on substrate 450. In some implementations, peripheral device 452 is used to form the peripheral circuit including one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits may use CMOS technology which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

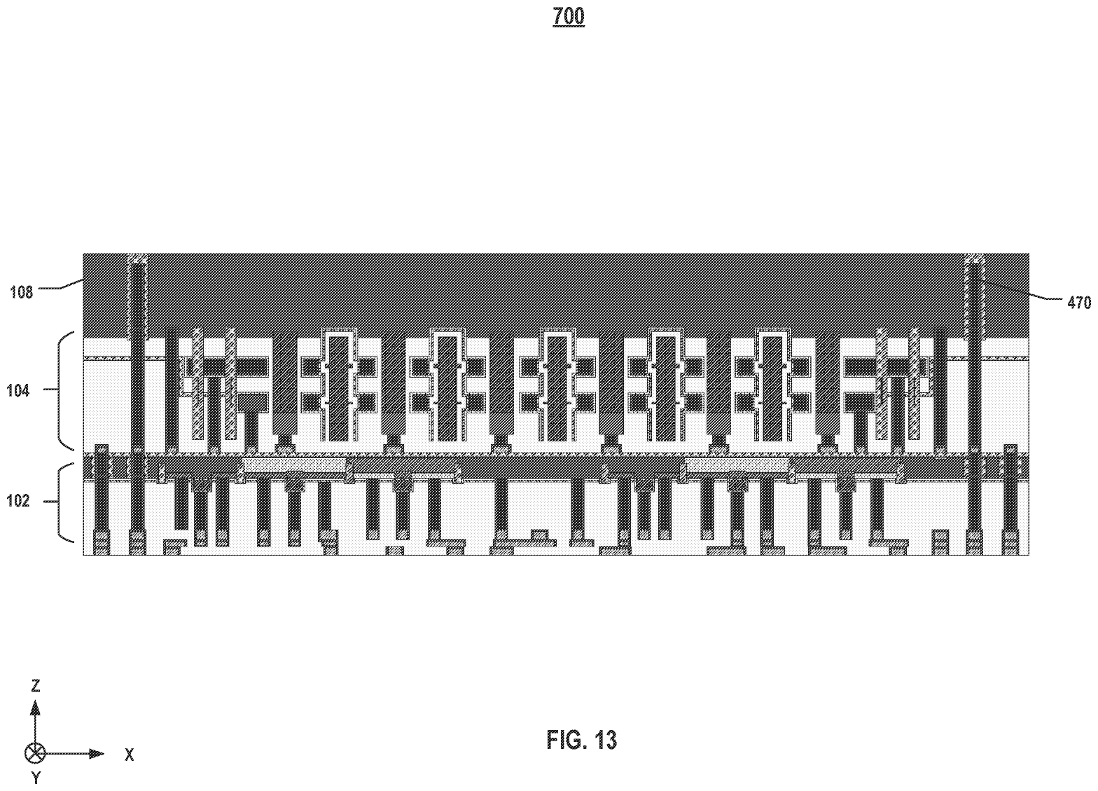

As shown in FIG. 13, the structure including substrate 108, first semiconductor structure 102, and second semiconductor structure 104, is flipped over. In some implementations, contact 470 is formed extending through substrate 108. Contact structure 470 may include conductive materials including, but not limited to, W, Co, Cu, Al, silicides, or any combination thereof. In some implementations, contact structures 470 includes a via surrounded by a dielectric spacer (e.g., having silicon oxide) to electrically separate the via from substrate 108.

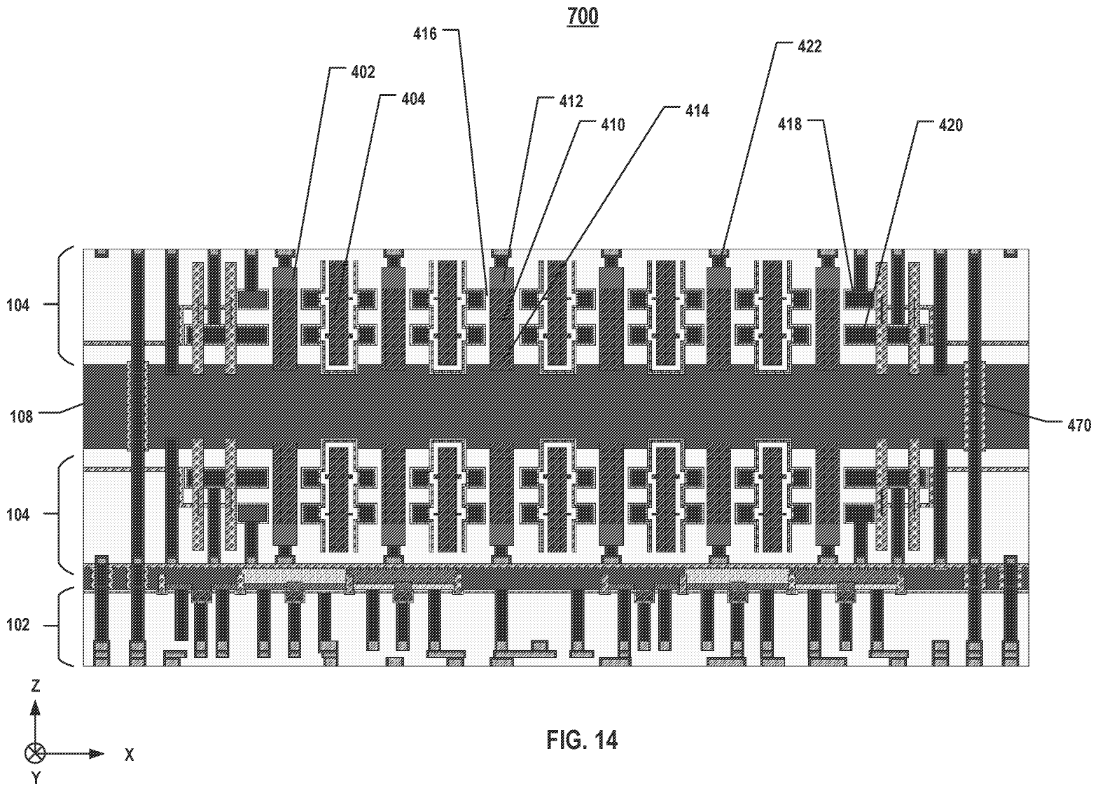

As shown in FIG. 14 and operation 1606 in FIG. 16, a second memory array, e.g., second semiconductor structure 104, including a plurality of second memory cells, e.g., memory cell 402, is formed on a second surface of substrate 108 opposite to the first surface. The formation process of second semiconductor structure 104 on the second surface of substrate 108 may be similar to the formation process of second semiconductor structure 104 on the first surface of substrate 108. The second memory array may include a second channel structure, e.g., semiconductor body 410, extending in the z-direction, and a second word line, e.g., word line 418, and a second plate line, e.g., plate line 420, extending in the x-direction.

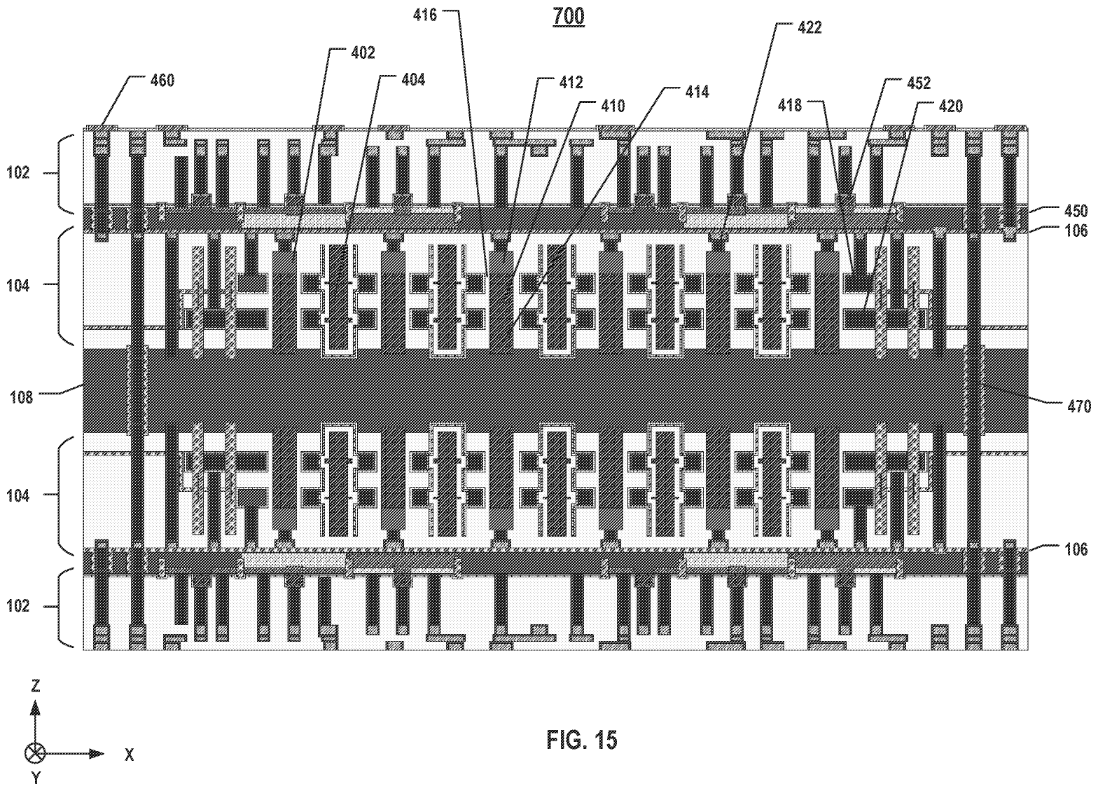

As shown in FIG. 15 and operation 1608 in FIG. 16, a third semiconductor layer, e.g., substrate 450, is formed on second semiconductor structure 104. Then, a second peripheral circuit, e.g., first semiconductor structure 102, including a second peripheral device, e.g., peripheral device 452, is formed on substrate 450. The formation process of first semiconductor structure 102 on the second surface of substrate 108 may be similar to the formation process of first semiconductor structure 102 on the first surface of substrate 108.

By utilizing method 1600 to form the memory device, memory devices 400, 500, 600, and/or 700 may have a vertical arrangement of the source/drain terminals, which can reduce the area of the transistor as well as simplify the layout of the interconnect structures and reduce the fabrication complexity. In addition, memory devices 400, 500, 600, and/or 700 do not need a capacitor storage device to store data, and memory cells 402 on the same surface of substrate 108 may form a common source architecture to increase the cell density. Furthermore, memory cells 402 may be formed on two opposite surfaces of substrate 108 to further increase the density of memory devices 400, 500, 600, and/or 700.

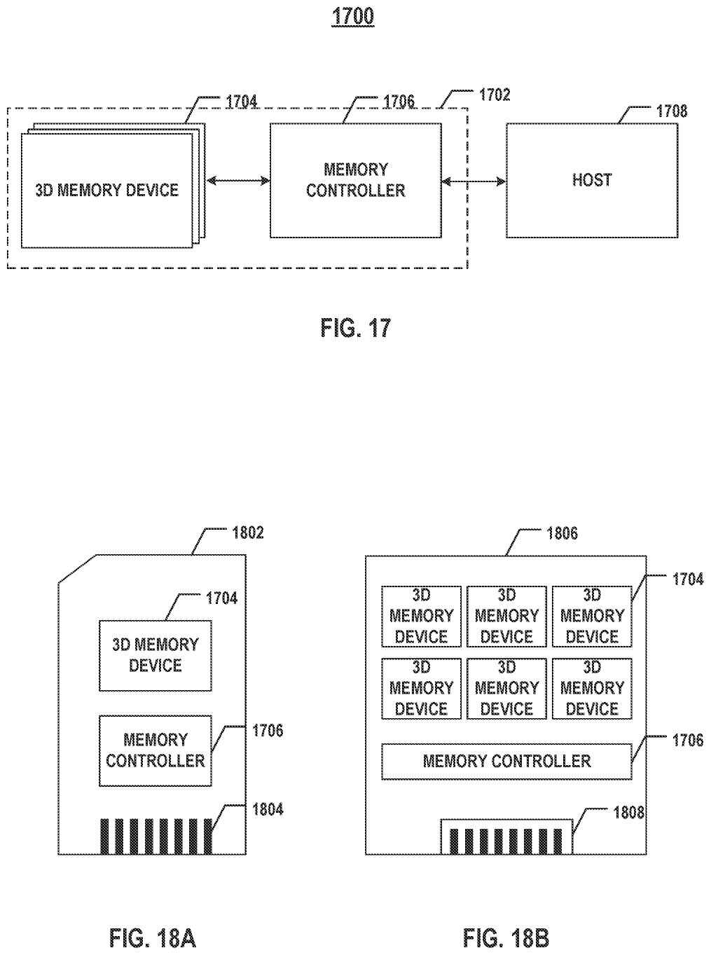

FIG. 17 illustrates a block diagram of an exemplary system 1700 having a memory device, according to some aspects of the present disclosure. System 1700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 17, system 1700 can include a host 1708 and a memory system 1702 having one or more memory devices 1704 and a memory controller 1706. Host 1708 can be a processor of an electronic device, such as a central processing unit (CPU), or a system-on-chip (SoC), such as an application processor (AP). Host 1708 can be configured to send or receive data to or from memory devices 1704.

Memory device 1704 can be any memory device disclosed in the present disclosure. As disclosed above in detail, memory device 1704, such as a DFM device, may have a controlled and predefined discharge current in the discharge operation of discharging the bit lines. Memory controller 1706 is coupled to memory device 1704 and host 1708 and is configured to control memory device 1704, according to some implementations. Memory controller 1706 can manage the data stored in memory device 1704 and communicate with host 1708. For example, memory controller 1706 may be coupled to memory device 1704, such as memory devices 400, 500, 600, and/or 700 described above, and memory controller 1706 may be configured to control the operations of the memory cell, e.g., the DFM cell, through the peripheral device.

In some implementations, memory controller 1706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1706 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1706 can be configured to control operations of memory device 1704, such as read, erase, and program operations. Memory controller 1706 can also be configured to manage various functions with respect to the data stored or to be stored in memory device 1704 including, but not limited to bad-block management, garbage collection, logical-to-physical address conversion, wear leveling, etc. In some implementations, memory controller 1706 is further configured to process error correction codes (ECCs) with respect to the data read from or written to memory device 1704. Any other suitable functions may be performed by memory controller 1706 as well, for example, formatting memory device 1704. Memory controller 1706 can communicate with an external device (e.g., host 1708) according to a particular communication protocol. For example, memory controller 1706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1706 and one or more memory devices 1704 can be integrated into various types of storage devices, for example, be included in the same package, such as a universal Flash storage (UFS) package or an eMMC package. That is, memory system 1702 can be implemented and packaged into different types of end electronic products. In one example as shown in FIG. 18A, memory controller 1706 and a single memory device 1704 may be integrated into a memory card 1802. Memory card 1802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1802 can further include a memory card connector 1804 coupling memory card 1802 with a host (e.g., host 1708 in FIG. 17). In another example as shown in FIG. 18B, memory controller 1706 and multiple memory devices 1704 may be integrated into an SSD 1806. SSD 1806 can further include an SSD connector 1808 coupling SSD 1806 with a host (e.g., host 1708 in FIG. 17). In some implementations, the storage capacity and/or the operation speed of SSD 1806 is greater than those of memory card 1802.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a first semiconductor layer;
a first memory array disposed on a first side of the first semiconductor layer, comprising:
first memory cells; and
first split structures;
a second memory array disposed on a second side of the first semiconductor layer opposite to the first side, comprising:
second memory cells; and
second split structures; and
a first peripheral circuit comprising a first peripheral device disposed on the first memory array.

2. The memory device of claim 1, wherein each first memory cell comprises:
a first semiconductor body extending in a first direction, wherein a first end of the first semiconductor body is in contact with the first semiconductor layer;
a first word line extending in a second direction perpendicular to the first direction;
a first plate line extending in the second direction; and
a first dielectric layer disposed between the first semiconductor body and the first word line and the first plate line.

3. The memory device of claim 2, wherein the first plate line comprises conductive lines extending in the second direction.

4. The memory device of claim 2, wherein the first semiconductor body and the first semiconductor layer comprise a same semiconductor material.

5. The memory device of claim 1, wherein the first peripheral circuit is disposed on a first side of a second semiconductor layer and a second side of the second semiconductor layer opposite to the first side is bonded to the first memory array.

6. The memory device of claim 1, wherein the first peripheral circuit is disposed on a first side of a second semiconductor layer and a second side of the second semiconductor layer opposite to the first side is formed a pad-out structure.

7. The memory device of claim 1, wherein each first split structure comprises:
a split core; and
a second dielectric layer surrounding the split core,
wherein the second dielectric layer is disposed between a first end of the split core and the first semiconductor layer.

8. The memory device of claim 1, wherein each first split structure comprises:
a split core; and
a second dielectric layer surrounding the split core,
wherein a first end of the split core is in contact with the first semiconductor layer.

9. The memory device of claim 1, further comprising:
a contact structure penetrating the first semiconductor layer, the first memory array, and the second memory array,
wherein the contact structure is in contact with the first peripheral circuit and the second peripheral circuit.

10. A memory device, comprising:
a first semiconductor layer;
a first memory array comprising first memory cells disposed on a first side of the first semiconductor layer, wherein each first memory cell comprises:
a first semiconductor body extending in a first direction, wherein a first end of the first semiconductor body is in contact with the first semiconductor layer;
a first word line extending in a second direction perpendicular to the first direction;
a first plate line extending in the second direction; and
a first dielectric layer disposed between the first semiconductor body and the first word line and the first plate line;
a second memory array comprising second memory cells disposed on a second side of the first semiconductor layer opposite to the first side, wherein each second memory cell comprises:
a second semiconductor body extending in the first direction, wherein a first end of the second semiconductor body is in contact with the first semiconductor layer;
a second word line extending in the second direction;
a second plate line extending in the second direction; and
a second dielectric layer disposed between the second semiconductor body and the second word line and the second plate line; and
a first peripheral circuit comprising a first peripheral device disposed on the first memory array.

11. The memory device of claim 10, wherein the first memory array further comprises:
a plurality of first split structures, wherein each first split structure is disposed between two adjacent first memory cells.

12. The memory device of claim 11, wherein each first split structure comprises:
a split core; and
a third dielectric layer surrounding the split core,
wherein the third dielectric layer is disposed between a first end of the split core and the first semiconductor layer.

13. The memory device of claim 11, wherein each first split structure comprises:
a split core; and
a third dielectric layer surrounding the split core,
wherein a first end of the split core is in contact with the first semiconductor layer.

14. A method for forming a memory device, comprising:
forming a first memory array comprising first memory cells on a first surface of a first semiconductor layer, wherein the first memory array comprises a first channel structure extending in a first direction, and a first word line and a first plate line extending in a second direction perpendicular to the first direction;
forming a first peripheral circuit comprising a first peripheral device on the first memory array;
forming a second memory array comprising second memory cells on a second surface of the first semiconductor layer opposite to the first surface, wherein the second memory array comprises a second channel structure extending in the first direction, and a second word line and a second plate line extending in the second direction; and
forming a second peripheral circuit comprising a second peripheral device on the second memory array.

15. The method of claim 14, wherein forming the first memory array comprising first memory cells on the first surface of the first semiconductor layer, comprising:
forming a dielectric stack comprising interleaved first dielectric layers and second dielectric layers on the first semiconductor layer;
forming the first channel structure in the dielectric stack extending in the first direction;
replacing the second dielectric layers with the first word line and the first plate line extending in the second direction; and
forming a bit line in contact with the first channel structure.

16. The method of claim 15, further comprising:
forming a split structure between two adjacent first memory cells.

17. The method of claim 16, wherein forming the split structure between two adjacent first memory cells, comprises:
forming a split opening penetrating the dielectric stack extending in the first direction to expose the first semiconductor layer;
forming a third dielectric layer in sidewalls of the split opening; and
forming a split core in the split opening.

18. The method of claim 17, wherein a bottom surface of the split core is below a top surface of the first semiconductor layer.

19. The method of claim 14, wherein forming the first peripheral circuit comprising the first peripheral device on the first memory array, comprises:
forming a second semiconductor layer on the first memory array; and
forming the first peripheral circuit comprising the first peripheral device on the second semiconductor layer.

20. The method of claim 14, wherein forming the first peripheral circuit comprising the first peripheral device on the first memory array, comprises:
forming the first peripheral circuit comprising the first peripheral device on a second semiconductor layer, and
bonding the first peripheral circuit with the first memory array in a face-to-face manner.
